(19) United States
(12) Patent Application Publication
(10) Pub. No.: US 2018/0159009 A1
(43) Pub. Date: Jun. 7, 2018

(54) METHOD FOR PRODUCING AN ELECTRONIC COMPONENT WITH A CARRIER ELEMENT AND ELECTRONIC COMPONENT WITH A CARRIER ELEMENT

(71) Applicant: OSRAM Opto Semiconductors GmbH, Regensburg (DE)

(72) Inventors: Thomas SCHWARZ, Regensburg (DE); Michael ZITZLSPERGER, Regensburg (DE)

(21) Appl. No.: 15/576,043

(22) PCT Filed: Apr. 28, 2016
(86) PCT No.: PCT/EP2016/059517

§ 371 Date: Nov. 21, 2017

(30) Foreign Application Priority Data
May 28, 2015 (DE) 102015108420.1

(51) Int. Cl. H01L 33/64; H01L 25/075; H01L 33/48; H01L 33/50; H01L 33/56; H01L 33/58; H01L 33/62

(52) U.S. Cl. CPC H01L 33/641; H01L 25/0753; H01L 33/486; H01L 33/502; H01L 2933/0075; H01L 33/58; H01L 33/62; H01L 33/647; H01L 33/56

(57) ABSTRACT

The invention relates to a method for producing an electronic component with a carrier element (100), with the steps: producing the carrier element (100), having the steps A) providing a first metal layer (1) comprising a first metal material, wherein the first metal layer (1) has a first and a second main surface (10, 11) which face away from one another, B) applying a second metal layer (2) comprising a second metal material on at least one of the main surfaces (10, 11), C) converting a part of the second metal layer (2) into a dielectric ceramic layer (3), wherein the second metal material forms a component of the ceramic layer (3), and the ceramic layer (3) forms a surface (30) which faces away from the first metal layer (1) and is above the second metal layer (2);—arranging at least one electronic semiconductor chip (21) on the carrier element (100). The invention further relates to an electronic component with a carrier element (100).

This patent application claims the priority of the German patent application 10 2015 108 420.1, the disclosure content of which is hereby incorporated by reference.

A method for producing a carrier element, a carrier element, a method for producing an electronic component with a carrier element and an electronic component with a carrier element are provided.

For electronic applications, substrates are often needed which have high thermal conductivity together with insulating properties, in particular high electrical insulating strength, and high mechanical strength at the same time as low costs. Substrates of this type are used e.g. for mounting semiconductor chips during so-called COB assembly (COB: chip-on-board) or together with surface-mounted SMD components (SMD: surface-mounted device). It is known, for example, to use ceramic substrates composed of e.g. aluminum oxide, aluminum nitride or silicon nitride for this purpose. Furthermore, printed circuit boards such as e.g. metal core boards (MCBs) are known which consist of a copper or aluminum substrate with an organic dielectric material with inorganic fillers applied on one or both sides. Furthermore, copper-ceramic-copper laminates are also known by the catchword “direct bonded copper” (DCB).

Objects of specific embodiments are to provide a method for producing a carrier element, in particular for an electronic component, a carrier element of this type, a method for producing an electronic component with a carrier element and an electronic component with a carrier element.

These objects are achieved by methods and items according to the independent claims. Advantageous embodiments and developments of the method and items are characterized in the dependent claims and can also be taken from the following description and the drawings.

According to at least one embodiment, in a method for producing a carrier element a first metal layer is provided. The first metal layer comprises in particular a first and a second main surface which face away from one another. In particular, those areas having the greatest extension of the surfaces of the first metal layer are referred to as a main surface. In particular, the first metal layer can be provided as a metal film or metal sheet having two main surfaces opposite one another, which are connected to one another by side surfaces, wherein the side surfaces can have a smaller surface area than the main surfaces. The first metal layer can be provided in unpatterned form and thus as a coherent sheet- or film-shaped structure. Alternatively, it may also be possible to provide the first metal layer in patterned form, that is e.g. with recesses, openings, holes, indentations and/or bulges. For example, a patterned first metal layer can be provided in the form of a patterned lead frame. The first metal layer can in particular be self-supporting. This means that the first metal layer, owing to a suitable composition, thickness and structure, has sufficient stability for the method steps described below and in the finished carrier element can be the element that provides the carrier element with its basic stability and strength.

According to a further embodiment, a second metal layer is applied on at least one of the main surfaces. This means that either a second metal layer is applied on the first main surface or a second metal layer is applied on the second main surface or a second metal layer is applied on each of the first and second main surfaces. In particular, the second metal layer is applied on the respective main surface of the first metal layer over a large area and coherently, such that the second metal layer preferably covers the entire area of the main surface on which it is applied. If a second metal layer is applied on each of the two main surfaces, these two second metal layers therefore preferably each cover the respective main surfaces over a large area and coherently. Moreover, it may also be possible that side surfaces of the first metal layer which connect the main surfaces to one another are also covered with the second metal layer. If the first metal layer has a patterning, e.g. in the form of openings, holes or recesses, it may in particular also be possible that the second metal layer is applied on side walls of these structures.

According to a further embodiment, the first metal layer comprises a first metal material and the second metal layer comprises a second metal material. The first metal material of the first metal layer can in particular be different from the second metal material of the second metal layer. The first metal material is formed in particular by a material having high thermal conductivity and/or high mechanical strength, such that the first metal layer is in particular self-supporting as described above. The first metal material can in particular be formed by one or more of the following materials: copper, nickel, titanium, steel, stainless steel and alloys therewith. The second metal material can in particular be formed by a material which can be applied on the first metal material by electroplating. In particular, the second metal material can comprise or be composed of aluminum, in particular aluminum with a purity of greater than or equal to 99.99%.

According to a further embodiment, the second metal layer is applied on the first metal layer by means of an electroplating method. In order to apply the second metal material, in particular aluminum, in the highest possible purity as a second metal layer, it is particularly advantageous if the electroplating method takes place with the exclusion of oxygen and water.

According to a further embodiment, the second metal layer is applied directly on the first metal layer. This means in other words that, after the second metal layer has been applied on one or both main surfaces of the first metal layer, a laminate is provided for further processing, which is provided from the first metal layer and a second metal layer directly thereon, or from the first metal layer between two second metal layers in direct contact therewith. In particular, it may be possible to apply aluminum as a second metal material on one of the above-mentioned first metal materials without an intermediate layer and thus directly on one or both main surfaces of the first metal layer. This can facilitate the application of layers.

According to a further embodiment, part of the second metal layer is converted to a dielectric ceramic layer. In particular, the conversion can be started from an external side of the second metal layer, which is formed by a surface of the second metal layer facing away from the first metal layer. In other words, the process for converting part of the second metal layer is started from an external side or from both external sides of the laminate composed of the first metal layer and one or two second metal layers on one or both main surfaces of the first metal layer. In particular, the second metal material can form part of the ceramic layer after conversion. The ceramic layer can form a surface over the second metal layer facing away from the first metal layer. This means in other words that, after the conversion of part of the second metal layer, the unconverted part of the second metal layer is arranged between the first metal layer and the dielectric ceramic layer. If a second metal layer is applied only on one main surface of the first metal layer, a three-layer laminar composite is produced by the conversion of part of the second metal layer, which is formed by the first metal layer, on this the non-converted part of the second metal layer, and over these the dielectric ceramic layer. If a second metal layer is applied on both main surfaces of the first metal layer, a five-layer laminar composite is produced by the conversion of part of each of the second metal layers, which is formed by a dielectric ceramic layer on which an unconverted part of a second metal layer is arranged, over which is the first metal layer, and on this again an unconverted part of a second metal layer and over this a further dielectric ceramic layer.

According to a further embodiment, the ceramic layer is produced over a large area and coherently, such that the dielectric ceramic layer covers the unconverted part of the second metal layer over a large area and coherently. Thus, in particular, the second metal layer and the ceramic layer can both be applied or produced over a large area and coherently on at least one of the main surfaces of the first metal layer. This can also mean that the remaining second metal layer is entirely surrounded by the first metal layer and the dielectric ceramic layer.

According to a further embodiment, the dielectric ceramic layer comprises a material which is formed by an oxide of the second metal material. If the second metal material comprises or consists of aluminum, the dielectric ceramic layer can in particular comprise or be formed by aluminum oxide.

According to a further embodiment, the dielectric ceramic layer is produced by means of electrolytic oxidation. In particular, it may be possible that the ceramic layer is not applied by anodizing, plasma-electrolytic oxidation or spray coating, since these methods usually create a more or less porous or cracked layer, and in the case of aluminum accordingly a more or less porous or cracked aluminum oxide layer. By electrolytic oxidation, on the other hand, an impervious, preferably as far as possible crack-free ceramic layer, and in the case of aluminum as a second metal material therefore ceramic aluminum oxide layer, can be produced which is particularly suitable for electrical applications. This can mean in particular that the ceramic layer has high thermal conductivity, e.g. greater than or equal to 5 W/mK, and high dielectric strength, in particular greater than or equal to 30 V/μm. In terms of the electrolytic oxidation method, aluminum can be particularly advantageous here as a second metal material whereas other materials, such as e.g. copper or steel, cannot be converted to an oxide that can be used for electronic applications.

To produce the dielectric ceramic layer, the first metal layer with the one second metal layer applied thereon or the two second metal layers applied thereon can be placed into an aqueous electrolyte solution. The ceramic layer in this case is formed as an oxygen-containing reaction product of the second metal material with the electrolyte solution. For example, an alkaline aqueous solution having e.g. a pH value of 9 or more can be used as the electrolyte solution. Moreover, it may be advantageous if the electrolyte solution has an electrical conductivity of more than 1 mS/cm. The aqueous electrolyte solution can comprise e.g. an alkali metal hydroxide, such as e.g. potassium hydroxide or sodium hydroxide. By using the electrolytic oxidation method, in particular a ceramic layer can be formed which has a nanocrystalline structure, i.e. a ceramic structure with crystalline particles having an average diameter of less than 200 nm and preferably of less than 100 nm. As a result of such a small particle size, the material of the dielectric ceramic layer can have great homogeneity and stability. A method for producing a ceramic layer by means of electrolytic oxidation is described e.g. in the document US 2014/0293554 A1, the relevant disclosure content of which is hereby incorporated in full by reference. The electrolytic oxidation method can in particular be advantageous in association with the previously described electroplating method for applying the second metal layer, since the electroplating method allows the second metal material to be applied with high purity, which in turn can lead, in the method for converting part of the second metal layer, to a high-quality ceramic material, in particular a high-quality nanoceramic.

Compared with e.g. a monolayer self-supporting aluminum substrate, which is provided with a dielectric ceramic layer by the method described here, the carrier element described here, which in addition to the second metal layer also comprises the first metal layer as a supporting element, has the advantage that a material can be used as a first metal material of the first metal layer which has a higher thermal conductivity than the second metal material of the second metal layer. Furthermore, a material can be used as a first metal material which is more stable than the second metal material, i.e. which has a higher modulus of elasticity, for example. As a result, it is possible to achieve easier processing of the carrier element when populating it with further components and/or during further electroplating methods, e.g. for producing traces. Moreover, a first metal material can be used for the first metal layer which can be more easily patterned, e.g. by etching, compared to the second metal material. As a result of this, finer structures can be achieved during patterning, and therefore ultimately resulting components can be given smaller dimensions. This can also result in a cost saving due to a gain in area. Furthermore, it may be possible to choose as the material of the first metal layer a material having a lower coefficient of thermal expansion compared with the second metal material, which, depending on the surrounding material such as e.g. chips and/or printed circuit boards, can result in lower mechanical stresses.

According to a further embodiment, a carrier element comprises a first metal layer with a first metal material. The first metal layer comprises in particular a first and a second main surface, which face away from one another. Furthermore, the carrier element comprises on at least one of the main surfaces a second metal layer with a second metal material. Furthermore, the carrier element comprises on the second metal layer a dielectric ceramic layer, wherein the second metal material of the second metal layer forms part of the ceramic layer and the ceramic layer forms a surface over the second metal layer facing away from the first metal layer.

According to a further embodiment, an electronic component comprises such a carrier element and at least one electronic semiconductor chip thereon.

According to a further embodiment, in a method for producing an electronic component, a carrier element is produced and on the carrier element at least one electronic semiconductor chip is arranged.

The embodiments and features mentioned above and below apply in the same way to the method for producing the carrier element, to the carrier element and to the method of producing the electronic component with the carrier element and to the electronic component with the carrier element.

According to a further embodiment, a patterned third metal layer is applied on the ceramic layer. The patterned third metal layer can at least partly form e.g. patterned contact surfaces and/or traces. In particular, the patterned third metal layer can be provided for mounting and/or electrically connecting further components which are arranged on the carrier element, e.g. one or more electronic semiconductor chips or other electronic or electrical components.

According to a further embodiment, the patterned third metal layer is applied by means of an electroplating method. To this end, a seed layer can be applied directly on the ceramic layer over a large area, on which the third metal layer is then applied by means of the electroplating method. A patterning of the third metal layer can be achieved e.g. by means of a photolithographic method. To this end, e.g. before carrying out the electroplating method for applying the third metal layer, a photoresist can be applied on the seed layer in a patterned manner. During the electroplating method, regions of the third metal layer are then applied only in regions in which no photoresist is present. The photoresist can then be removed. Alternatively, it may also be possible that the third metal layer is first applied on the seed layer over a large area. Next, a photoresist can be applied on the unpatterned third metal layer in a patterned manner. By means of an etching method, the third metal layer can be removed again in the regions in which no photoresist is present. Next, the photoresist can be removed.

In regions in which no third metal layer is arranged on the seed layer, the seed layer can then be removed again, so that in the regions in which no patterned third metal layer is present, the ceramic layer can form an external surface of the carrier element and the patterned regions of the patterned third metal layer are electrically insulated from one another. The third metal layer can comprise a third metal material, which in particular can have high conductivity and can be readily patterned, e.g. copper.

According to a further embodiment, the first metal layer is provided with at least one opening. The opening can extend in particular from one of the main surfaces into the first metal layer. In this case, it may also be possible in particular that the opening extends from the first main surface to the second main surface through the first metal layer. The opening has a wall surface. During the method steps described above, the second metal layer and the ceramic layer can be applied on the wall surface of the opening.

According to a further embodiment, according to the method steps described above a third metal layer is applied on the ceramic layer on the wall surface of the opening to form an electrical feed-through, which passes through the first metal layer and the second metal layer and the ceramic layer on the at least one main surface of the first metal layer.

The carrier element described here can be used in particular for an electronic component, in which at least one electronic semiconductor chip is mounted on the carrier element. The electronic semiconductor chip can in particular be mounted on the patterned third metal layer and/or can be electrically contacted by means thereof. In particular, the carrier element described here can therefore be provided for surface mounting or as a substrate for SMD components or as a substrate for non-SMD components, e.g. in the production of a so-called light kernel, an IGBT module, a substrate for a component for through-hole mounting or similar components.

Particularly advantageous aspects of the embodiments described above are provided below:

Aspect 1: A method for producing a carrier element, e.g. for use in an electronic component, has the following steps:
A) preparing a first metal layer with a first metal material, wherein the first metal layer comprises a first and a second main surface, which face away from one another,
B) applying a second metal layer with a second metal material on at least one of the main surfaces,
C) converting part of the second metal layer to a dielectric ceramic layer, wherein the second metal material forms part of the ceramic layer and the ceramic layer forms a surface over the second metal layer facing away from the first metal layer.

Aspect 2: The method according to Aspect 1, in which the first metal material comprises one or more materials selected from copper, nickel, titanium, steel, stainless steel and alloys therewith.

Aspect 3: The method according to Aspect 1 or 2, in which the second metal material comprises aluminum, in particular aluminum with a purity of greater than or equal to 99.99%.

Aspect 4: The method according to Aspect 1, 2 or 3, in which the second metal layer is applied on the first metal layer by means of an electroplating method.

Aspect 5: The method according to Aspect 4, in which the electroplating method takes place with the exclusion of oxygen and water.

Aspect 6: The method according to Aspect 1, 2, 3, 4 or 5, in which the ceramic layer is produced by means of electrolytic oxidation.

Aspect 7: The method according to Aspect 1, 2, 3, 4, 5 or 6, in which the second metal layer is applied directly on the first metal layer.

Aspect 8: The method according to Aspect 1, 2, 3, 4, 5, 6 or 7, in which the second metal layer and the ceramic layer are applied over a large area and coherently on at least one of the main surfaces of the first metal layer.

Aspect 9: The method according to Aspect 1, 2, 3, 4, 5, 6, 7 or 8, in which a patterned third metal layer is applied on the ceramic layer, wherein a seed layer is applied directly on the ceramic layer, on which seed layer the third metal layer is applied by means of an electroplating method.

Aspect 10: The method according to Aspect 9, in which the patterned third metal layer at least partly forms patterned contact surfaces and/or traces.

Aspect 11: The method according to Aspect 1, 2, 3, 4, 5, 6, 7, 8, 9 or 10, in which the first metal layer is provided with at least one opening and the second metal layer and the ceramic layer are applied on a wall surface of the opening.

Aspect 12: The method according to Aspect 11, in which a third metal layer is applied on the ceramic layer on the wall surface of the opening to form an electrical feed-through, which passes through the first metal layer and through the second metal layer and the ceramic layer on the at least one main surface of the first metal layer.

Aspect 13: The method according to Aspect 1, 2, 3, 4, 5, 6, 7, 8, 9, 10, 11 or 12, in which method steps B and C are performed on each of the two main surfaces.

Aspect 14: A carrier element, e.g. for use in an electronic component, comprising

a first metal layer with a first metal material and with a first and second main surface, which face away from one another,

on at least one of the main surfaces a second metal layer with a second metal material and

on the second metal layer a dielectric ceramic layer, wherein the second metal material forms part of the ceramic layer and the ceramic layer forms a surface over the second metal layer facing away from the first metal layer.

Aspect 15: The carrier element according to Aspect 14, wherein the first metal material comprises one or more materials selected from copper, nickel, titanium, steel, stainless steel and alloys therewith and the second metal material comprises aluminum, in particular aluminum with a purity of greater than or equal to 99.99%.

Aspect 16: The carrier element according to Aspect 14 or 15, wherein the second metal layer is arranged directly on the first metal layer and the ceramic layer is arranged directly on the second metal layer.

Aspect 17: The carrier element according to Aspect 14, 15 or 16, wherein on the ceramic layer a patterned third metal layer is arranged, which at least partly forms patterned contact surfaces and/or traces.

Aspect 18: The carrier element according to Aspect 14, 15, 16 or 17, wherein

the first metal layer has at least one opening,

the second metal layer and the ceramic layer are arranged on a wall surface of the opening and

a third metal layer is arranged on the ceramic layer on the wall surface of the opening to form an electrical feed-through, which passes through the first metal layer and through the second metal layer and the ceramic layer on the at least one main surface of the first metal layer.

Aspect 19: The carrier element according to Aspect 14, 15, 16, 17 or 18, wherein the carrier element comprises on each of the main surfaces of the first metal layer a second metal layer and over this a ceramic layer.

Further advantages, advantageous embodiments and developments can be taken from the exemplary embodiments described below in association with the figures.

The figures show the following:

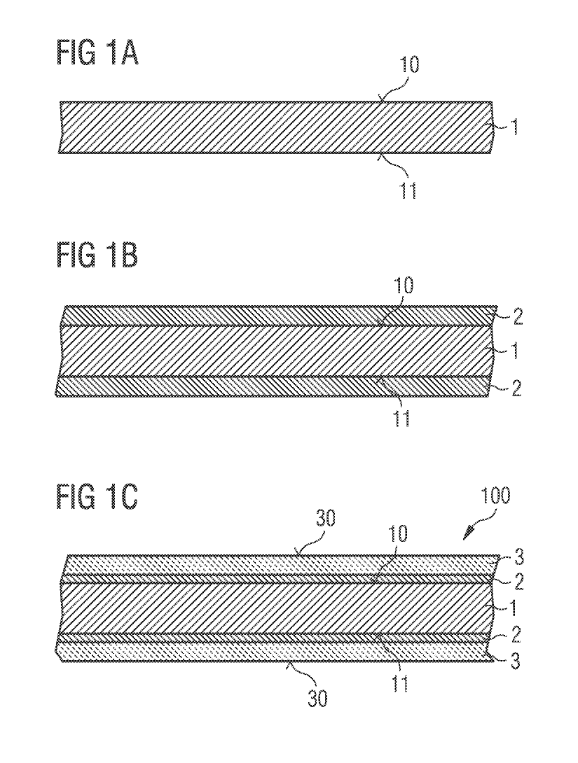

FIGS. 1A to 1C show schematic illustrations of method steps of a method for producing a carrier element according to an exemplary embodiment,

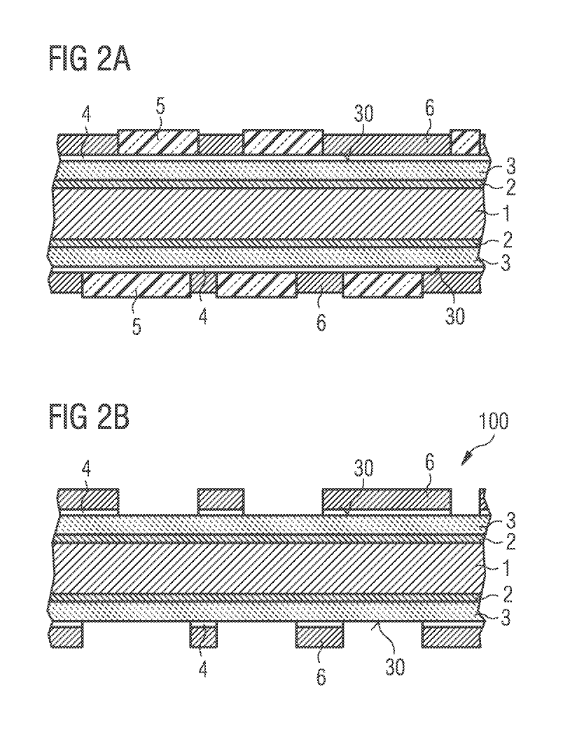

FIGS. 2A and 2B show schematic illustrations of method steps for producing a carrier element according to a further exemplary embodiment,

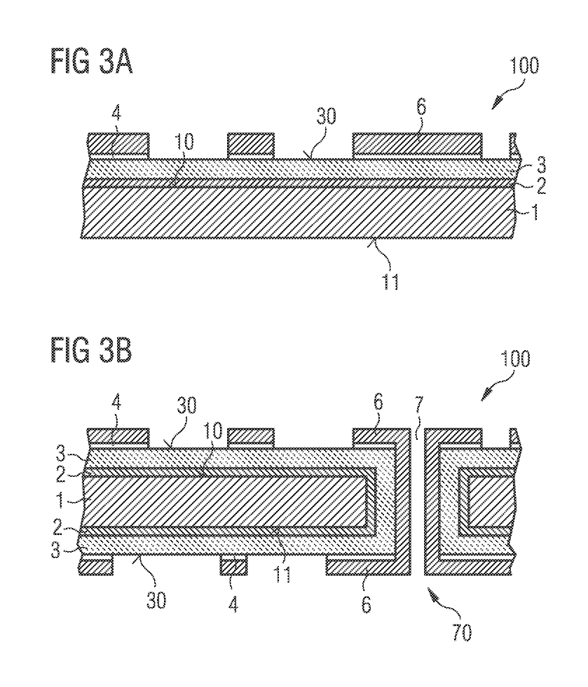

FIGS. 3A and 3B show schematic illustrations of carrier elements according to further exemplary embodiments,

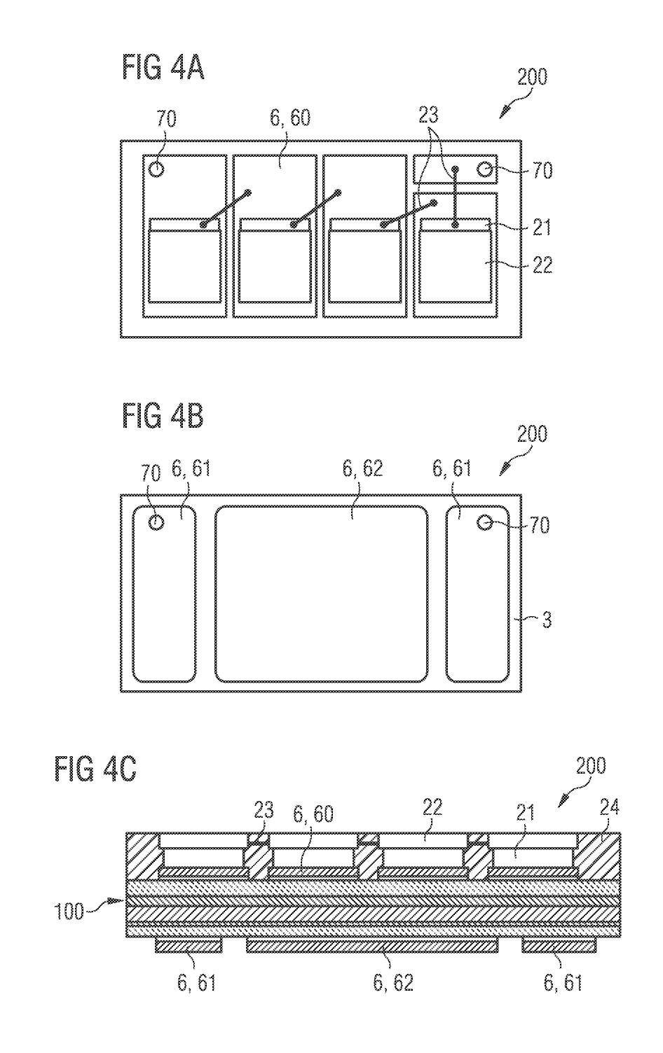

FIGS. 4A to 7B show schematic illustrations of electronic components with a carrier element according to further exemplary embodiments.

In the exemplary embodiments and figures, identical or similar elements or elements having the same effect can be provided with the same reference numbers. The elements illustrated and the size ratios to one another thereof should not be considered as being to scale; rather, to illustrate them better and/or to make them easier to understand, the size of individual elements such as e.g. layers, parts, components and areas may be exaggerated.

In FIGS. 1A to 1C, an exemplary embodiment of method steps of a method for producing a carrier element 100, which can be used in particular for an electronic component, is shown. To this end, in a first method step, as shown in a section in FIG. 1A, a first metal layer 1 is provided with a first metal material. The first metal layer 1 is in particular in the form of a metal film or metal sheet and can comprise or be composed of copper, for example, as a first metal material. Alternatively, the first metal layer can also comprise another metal material, in particular one or more of the materials mentioned above in the general part. The first metal layer 1 has a first main surface 10 and a second main surface 11, wherein the main surfaces 10, 11 face away from one another. The first metal layer 1 is self-supporting and can be provided as an unpatterned metal film or metal sheet or as a patterned metal film or metal sheet. For example, the first metal layer can be formed by a patterned lead frame. The first metal layer 1 can be in the form of e.g. a so-called QFN lead frame, a stamped lead frame, a pressed laser heat sink or similar.

In a further method step, as shown in FIG. 1B, on at least one of the main surfaces 10, 11 of the first metal layer 1 a second metal layer 2 with a second metal material is applied. In the exemplary embodiment shown, a second metal layer with a second metal material is applied on each of the main surfaces 10, 11. The second metal material can in particular comprise or be composed of aluminum.

The second metal layer is applied on each of the main surfaces 10, 11 by means of an electroplating method. In order to achieve the highest possible purity of the second metal material, in particular of greater than or equal to 99.99%, the electroplating method is performed with the exclusion of oxygen and water. As a result, the multilayer laminate shown in FIG. 1B, composed of the first metal layer 1 and the second metal layers 2 on the main surfaces 10, 11 of the first metal layer 1, is produced.

The electroplating method can be performed directly on the first metal layer 1, so that no further layers are present between the second metal layers 2 and the first metal layer 1 on the main surfaces 10, 11 of the first metal layer 1 and the second metal layers 2 are arranged directly on the first metal layer 1. The second metal layers 2 are applied on the first metal layer 1 in particular over a large area and coherently and thus covering the entire main surfaces 10, 11 as far as possible. Compared with a monolayer substrate, which is formed only by a self-supporting aluminum film, the formation of a laminate composed of the first metal layer and one or two second metal layers 2 on one or both main surfaces 10, 11 of the first metal layer 1 with or composed of copper can in particular have the following advantages:
Copper has significantly higher thermal conductivity than aluminum and aluminum alloys, and so the laminate shown in FIG. 1B, and therefore also the finished carrier element 100, have higher thermal conductivity than a monolayer aluminum film.
Copper is also significantly more stable than aluminum and in particular has a higher modulus of elasticity, which can result in greater ease of processing during assembly and a subsequent electroplating method.
The patterning of copper, e.g. for producing lead frames and in particular in etching methods, is easier than for aluminum. Compared to copper, aluminum can be etched only with difficulty and coarsely; in particular the etch factors are higher for aluminum.
Owing to finer structures of a copper lead frame as a first metal layer 1, smaller components can be produced, which may result in a cost saving, e.g. by a gain in area.
Copper has a lower coefficient of thermal expansion with 18 ppm/K compared to aluminum with 23 ppm/K and so, depending on the surrounding material, lower mechanical stresses can result.

The above-mentioned features and advantages can also apply mutatis mutandis to other first metal materials.

In a further method step, as shown in FIG. 1C, part of each of the second metal layers 2 is converted to a dielectric ceramic layer 3. The conversion of the second metal layers 2 takes place by means of an electrochemical method, in particular by means of electrolytic oxidation, as described above in the general part. As a result, a conversion of the second metal material of the second metal layer to a metal oxide is achieved from a surface of the second metal layers 2 facing away from the first metal layer 1. In the exemplary embodiment shown, therefore, the aluminum that forms the second metal material of the second metal layers 2 is converted to aluminum oxide. The second metal material thus forms part of the ceramic layers 3. In particular, the ceramic material of the dielectric ceramic layers 3 produced by the conversion method described here is formed as a nanocrystalline ceramic material, as described above in the general part. As a result of the electrolytic oxidation described above, in particular a ceramic layer 3 which is as impervious and crack-free as possible can be formed on the surface of each of the second metal layers 2, said ceramic layer 3 having high dielectric strength together with high thermal conductivity.

In particular, the conversion of the part of the second metal layers 2 is carried out in each case over a large area, so that the dielectric ceramic layers 3 cover the remaining second metal layers 2 over a large area and coherently. The ceramic layers 3 thus each form a surface 30 over the second metal layers 2 facing away from the first metal layer 1. In carrying out the method for converting part of each of the second metal layers 2 to dielectric ceramic layers 3, it is advantageous if at least a thin second metal layer 2 remains after the conversion, since as a result of this, good adhesion of the dielectric ceramic layers 3 on the first metal layer 1 can be achieved by means of the remaining second metal layers 2. Furthermore, it is possible to avoid a risk of an undefined conversion of the first metal material of the first metal layer 1 should the entire second metal material of the second metal layers 2 be used up.

The carrier element 100 produced in this way therefore has a five-layer construction in the exemplary embodiment shown, in which between two ceramic layers 3, two second metal layers 2 are arranged and between these in turn a first metal layer 1, wherein the said layers are each applied one directly on top of another.

Alternatively to the method shown, it may also be possible that a second metal layer 2 is applied only on one of the main surfaces 10, 11 and this is partly converted to a dielectric ceramic layer 3, so that the carrier element thus produced then has a three-layer construction and is formed by the first metal layer 1, directly on this the second metal layer 2 and directly on this the dielectric ceramic layer 3.

In association with FIGS. 2A and 2B, an exemplary embodiment of further method steps is described in the context of a method for producing a carrier element 100, in particular for use in an electronic component, which can follow the method steps shown in association with FIGS. 1A to 1C. In particular, in the method steps described below, a third metal layer 6 is applied on each of the ceramic layers 3, which can form e.g. patterned contact surfaces and/or traces.

As shown in FIG. 2A, a seed layer 4 is applied on the surface 30 of each of the ceramic layers 3 over a large area and in an unpatterned manner. On this, a photoresist 5 is applied in a patterned manner, representing a structure which is a negative of the patterned third metal layer 6 to be produced. By means of an electroplating method, the third metal layer 6 is grown through this in a patterned manner on the seed layer 4. For example, the third metal layer can comprise or be composed of copper.

Next, as shown in FIG. 2B, the photoresist 5 is removed. In regions in which no patterned third metal layer 6 is present, the seed layer 4 is also removed and so the surfaces 30 of the ceramic layers 3 form a surface of the carrier element 100 thus produced in the regions in which no third metal layer 6 is present, and the patterned regions of the third metal layer 6 are electrically insulated from one another.

Alternatively to applying a patterned photoresist 5 before carrying out the electroplating method for applying the patterned third metal layer 6, it may also be possible to apply the third metal layer 6 on the seed layer 4 in an unpatterned manner and over a large area and, following this, to apply a photoresist in a patterned manner. The photoresist in this case represents a structure which is a positive of the patterned third metal layer 6 to be produced. In regions in which the third metal layer 6 is not covered by the photoresist, the third metal layer 6 and the seed layer 4 can be removed so that, after a subsequent removal of the photoresist, the carrier element 100 shown in FIG. 2B is again obtainable.

In FIG. 3A, a further exemplary embodiment of a carrier element 100 is shown, which can be used in particular in an electronic component and which, compared to the exemplary embodiments described above, has only a single-sided arrangement of the second metal layer 2 and the ceramic layer 3 on only one main surface 10 of the first metal layer 1 as mentioned above in association with FIGS. 1A to 1C. Accordingly, a patterned third metal layer 6 is applied on the ceramic layer 3 only over the one main surface 10 of the first metal layer 1. An embodiment of this type with only a single-sided metallizing formed by the patterned third metal layer 6 can be advantageous e.g. if on the bottom of the carrier element 100 formed by the second main surface 11 of the first metal layer 1 heat is to be dissipated over a large area.

In FIG. 3B a further exemplary embodiment of a carrier element 100 is shown, which can be used in particular in an electronic component and which, compared to the preceding exemplary embodiments, has an opening 7. The opening 7 is already produced during the preparation of the first metal layer 1 so that, in the subsequent method steps described above, as can be seen in FIG. 3B, the second metal layer 2 and the dielectric ceramic layer 3 are also produced on the wall surface of the opening 7. The opening 7, which extends from the first main surface 10 to the second main surface 11 through the first metal layer 1, can be created e.g. by drilling, stamping, etching or with the aid of a laser.

The third metal layer 6 is likewise additionally applied on the wall surface of the opening 7, so that an electrical feed-through 70 can be formed, which passes through the first metal layer 1 and through the second metal layer 2 and the ceramic layer 3 on the main surfaces 10, 11 of the first metal layer 1 and thus electrically connects the top and the bottom of the carrier element 100 to one another.

In the following exemplary embodiments, electronic components 200 are described, which comprise carrier elements 100, which are produced according to the methods described in association with the preceding exemplary embodiments. To produce an electronic component like the components 200 shown below, in addition to the method steps and features described above, an electronic semiconductor chip is arranged on the carrier element 100. The electronic components 200 described below are, purely by way of example, in the form of optoelectronic components and in particular light-emitting electronic components. Alternatively, however, using the carrier elements 100 described here, other electronic components, in particular also with non-optoelectronic functionalities, can also be produced.

In FIGS. 4A to 4C, various views are shown of an electronic component 200, which comprises a carrier element 100 and at least one electronic semiconductor chip 21 on the carrier element 100. In particular, the electronic component 200 of the exemplary embodiment of FIGS. 4A to 4C is in the form of a so-called multichip SMD component, which comprises the carrier element 100 as an electrically insulating heat sink. In FIGS. 4A and 4B, top views of a top and a bottom of the component 200 are shown, wherein the potting 24 is not shown in FIG. 4A. In FIG. 4C, a sectional illustration of the component 200 is shown.

The electronic component 200 comprises a plurality of electronic semiconductor chips 21, each of which is in the form of a light-emitting semiconductor chip, in particular a light-emitting diode. On each of these, a wavelength conversion layer 22 is applied, which can convert at least part of the light generated by the light-emitting semiconductor chips 21 during operation to light with a different wavelength. Alternatively, it may also be possible that no wavelength conversion layer 22 is applied on one, more or all of the semiconductor chips 21. The semiconductor chips 21 are each arranged on and electrically connected to patterned contact surfaces 60, which are formed by parts of the patterned metal layer 6 described above. By means of bonding wires 23, the semiconductor chips 21 are connected together in series.

By means of through-connections 70 as described above, contact surfaces 60 on the top of the electronic component 200 are connected to contact surfaces 61 on the bottom of the electronic component 200 formed by a further patterned metal layer 3, so that by means of the contact surfaces 61 an electrical contacting of the electronic component 200 can take place. The contact surfaces 61 on the bottom of the electronic component 200 thus form an anode and a cathode for connecting the electronic component 200. Furthermore, on the bottom of the electronic component 200 a further contact surface 62 is formed, which is electrically insulated from the rest of the contact surfaces 61 and which is provided for a thermal connection of the electronic component 200 to an external heat sink.

On the top of the electronic component 200, furthermore, a potting 24 is applied, in which the semiconductor chips 21, at least partly the wavelength conversion layers 22 and the bonding wires are arranged. The potting 24 can be produced e.g. by means of a foil-assisted molding (FAM) method. Furthermore, it may also be possible that e.g. a dam is formed around the semiconductor chips 1, which is filled with the potting 24. The potting 24 can comprise or be composed of a plastics material, which can be transparent, reflective or light-absorbing and which can comprise fillers that are appropriate in this context.

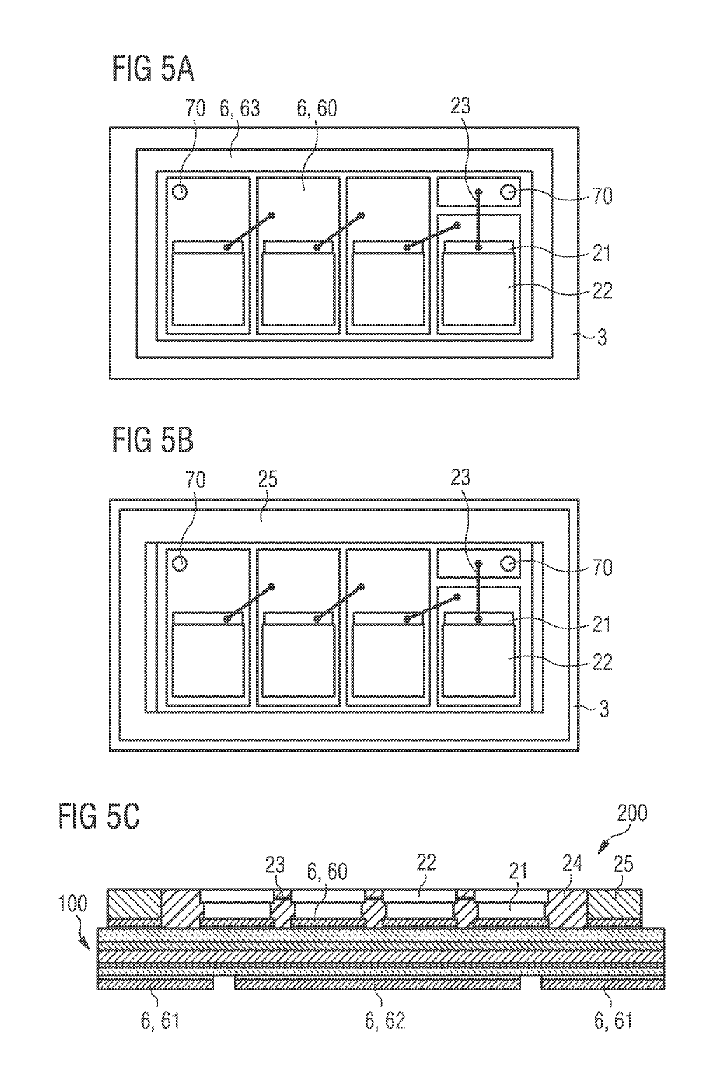

In association with FIGS. 5A to 5C, a further exemplary embodiment of an electronic component 200 is shown which, compared to the preceding exemplary embodiment, comprises a contact surface 63 surrounding the semiconductor chips 21 formed by part of the patterned third metal layer 6, on which a frame 25 is mounted which acts as a shade and thus as a so-called shutter-frame. The frame 25 can be composed of e.g. a metal or a plastic and can be adhesively bonded or soldered on the contact surface 63. The region surrounded by the frame 25 can in turn be filled with a potting 24, e.g. with a plastics material, comprising scattering particles or reflective particles, e.g. titanium dioxide particles. Compared to the finished component 200, which is shown in FIG. 5C, FIG. 5A shows a top view without a mounted frame 25 and without a potting 24, while FIG. 5B shows a top view with a frame 25 already mounted but still without a potting 24.

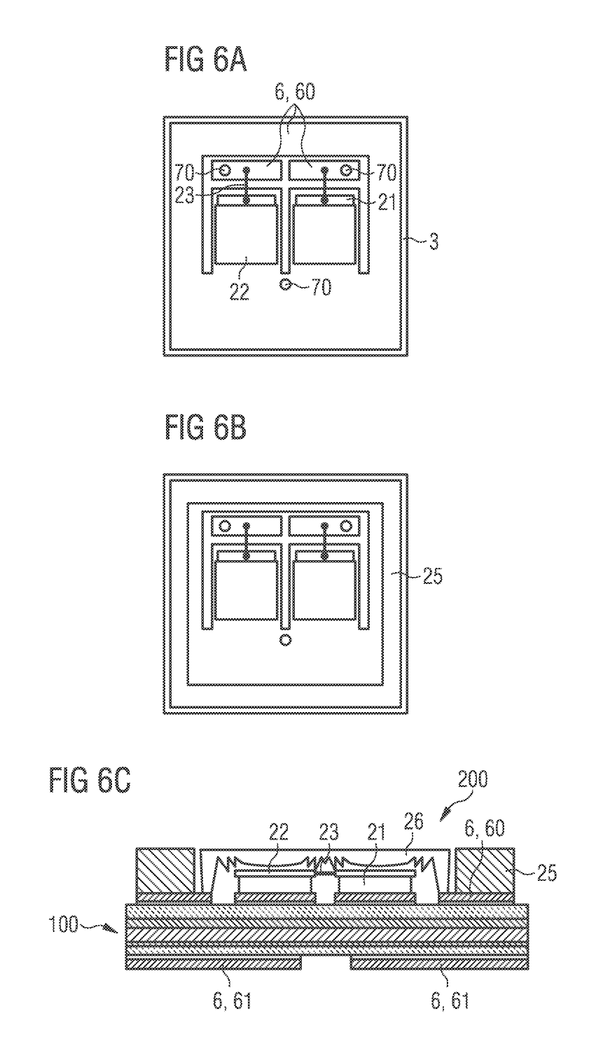

In association with FIGS. 6A to 6C, a further exemplary embodiment of an electronic component 200 is shown which, like the electronic component of the preceding exemplary embodiment, comprises a frame 25, which is applied surrounding semiconductor chips 21 on the carrier element 100 on a contact surface 60 appropriately provided for this purpose. FIGS. 6A and 6B each show a top view, one without and one with a frame 25 mounted. Within the frame 25 a lens 26, e.g. in the form of a Fresnel lens, is arranged over the semiconductor chips 21. Alternatively, another optical element can also be applied over the semiconductor chips 21. The frame 25 can facilitate handling of the electronic component 200 and represent a mechanical protection for the lens 26 while at the same time preventing light from being radiated laterally. The electronic component 200 of the exemplary embodiment of FIGS. 6A to 6C can be used e.g. as a flash light component.

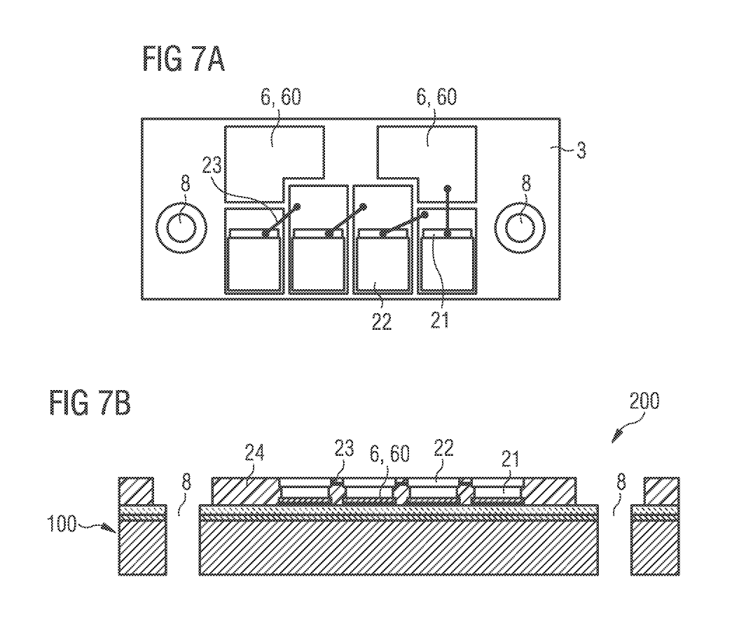

In association with FIGS. 7A and 7B, a further exemplary embodiment of an electronic component 200 is shown, comprising a carrier element 100 which, as described above in connection with FIG. 3A, comprises the second metal layer 2 and the dielectric ceramic layer 3 only on the first main surface 10, so that over the exposed second main surface 11 of the metal layer 1 of the carrier element 100 a thermal connection of the electronic component 200 is possible over a large area. As a result, direct mounting on a heat sink is possible, wherein for this purpose, as illustrated in the exemplary embodiment shown, e.g. holes 8 can also be provided in the carrier element 100 for mounting and/or easier positioning. In the top view shown in FIG. 7A, again the potting 24 is not shown.

The description with the aid of the exemplary embodiments does not limit the invention thereto. Rather, the invention comprises any new feature and any combination of features, which in particular includes any combination of features in the patent claims, even if this feature or this combination is not itself explicitly stated in the patent claims or exemplary embodiments.

### LIST OF REFERENCE NUMBERS

1 First metal layer
2 Second metal layer
3 Dielectric ceramic layer
4 Seed layer
5 Photoresist
6 Third metal layer
7 Opening
8 Hole
10, 11 Main surface
21 Semiconductor chip
22 Wavelength conversion layer
23 Bonding wire
24 Potting
25 Frame
26 Lens
10, 11 Main surface
30 Surface
70 Through-connection
60, 61, 62, 63 Contact surface
100 Carrier element
200 Electronic component

1. A method for producing an electronic component with a carrier element having the following steps:
production of the carrier element, comprising the following steps:
A) providing a first metal layer with a first metal material, wherein the first metal layer comprises a first and a second main surface, which face away from one another,
B) applying a second metal layer with a second metal material on at least one of the main surfaces,
C) converting part of the second metal layer to a dielectric ceramic layer, wherein the second metal material forms part of the ceramic layer and the ceramic layer forms a surface over the second metal layer facing away from the first metal layer;
arranging at least one electronic semiconductor chip on the carrier element.

2. The method according to claim 1, in which the first metal material comprises one or more materials selected from copper, nickel, titanium, steel, stainless steel and alloys therewith.

3. The method according to claim 1, in which the second metal material comprises aluminum, in particular aluminum with a purity of greater than or equal to 99.99%.

4. The method according to claim 1, in which the second metal layer is applied on the first metal layer by means of an electroplating method.

5. The method according to claim 4, in which the electroplating method takes place with the exclusion of oxygen and water.

6. The method according to claim 1, in which the ceramic layer is produced by means of electrolytic oxidation.

7. The method according to claim 1, in which the second metal layer is applied directly on the first metal layer.

8. The method according to claim 1, in which the second metal layer and the ceramic layer are applied over a large area and coherently on at least one of the main surfaces of the first metal layer.

9. The method according to claim 1, in which a patterned third metal layer is applied on the ceramic layer, wherein a seed layer is applied directly on the ceramic layer, on which seed layer the third metal layer is applied by means of an electroplating method.

10. The method according to claim 9, in which the patterned third metal layer at least partly forms patterned contact surfaces and/or traces.

11. The method according to claim 1, in which the first metal layer is provided with at least one opening and the second metal layer and the ceramic layer are applied on a wall surface of the opening.

12. The method according to claim 11, in which a third metal layer is applied on the ceramic layer on the wall surface of the opening to form an electrical feed-through, which passes through the first metal layer and through the second metal layer and the ceramic layer on the at least one main surface of the first metal layer.

13. The method according to claim 1, in which method steps B and C are performed on each of the two main surfaces.

14. An electronic component comprising a carrier element and at least one electronic semiconductor chip on the carrier element, the carrier element comprising
a first metal layer with a first metal material and with a first and second main surface, which face away from one another,
on at least one of the main surfaces a second metal layer with a second metal material and
on the second metal layer a dielectric ceramic layer, wherein the second metal material forms part of the ceramic layer and the ceramic layer forms a surface over the second metal layer facing away from the first metal layer.

15. The electronic component according to claim 14, wherein the first metal material comprises one or more materials selected from copper, nickel, titanium, steel, stainless steel and alloys therewith and the second metal material comprises aluminum, in particular aluminum with a purity of greater than or equal to 99.99%.

16. The electronic component according to claim 14, wherein the second metal layer is arranged directly on the first metal layer and the ceramic layer is arranged directly on the second metal layer.

17. The electronic component according to claim 14, wherein on the ceramic layer a patterned third metal layer is arranged, which at least partly forms patterned contact surfaces and/or traces.

18. The electronic component according to claim 14, wherein
the first metal layer comprises at least one opening,
the second metal layer and the ceramic layer are arranged on a wall surface of the opening and
a third metal layer is arranged on the ceramic layer on the wall surface of the opening to form an electrical feed-through, which passes through the first metal layer and through the second metal layer and the ceramic layer on the at least one main surface of the first metal layer.

19. The electronic component according to claim 14, wherein the carrier element comprises on each of the main surfaces of the first metal layer a second metal layer, and over this a ceramic layer.

20. The method according to claim 1, in which a patterned third metal layer is applied on the ceramic layer, which at least partly forms patterned contact surfaces and/or traces through which the electronic semiconductor chip is electrically connected.
